(19) United States
(12) Patent Application Publication
(10) Pub. No.: US 2023/0287270 A1
(43) Pub. Date: Sep. 14, 2023

(54) SILICON ETCHING LIQUID, AND METHOD FOR PRODUCING SILICON DEVICE AND METHOD FOR PROCESSING SILICON SUBSTRATE, EACH USING SAID ETCHING LIQUID

(71) Applicant: TOKUYAMA CORPORATION, Yamaguchi (JP)

(72) Inventors: Yoshiki SEIKE, Yamaguchi (JP); Manami OSHIO, Yamaguchi (JP); Seiji TONO, Yamaguchi (JP)

(73) Assignee: TOKUYAMA CORPORATION, Yamaguchi (JP)

(21) Appl. No.: 18/017,765

(22) PCT Filed: Jul. 29, 2021
(86) PCT No.: PCT/JP2021/028031

§ 371 Date: Jan. 24, 2023

(30) Foreign Application Priority Data
Jul. 31, 2020 (JP) 2020-131244
Dec. 24, 2020 (JP) 2020-215649

(51) Int. Cl. C09K 13/00; H01L 21/306

(52) U.S. Cl. CPC C09K 13/00; H01L 21/30604

(57) ABSTRACT

A silicon etching liquid which contains a quaternary ammonium hydroxide represented by formula (1), a quaternary ammonium iodide represented by formula (2), and water. (1): R¹¹R¹²R¹³R¹⁴N⁺·OH⁻ (In formula (1), each of R¹¹, R¹², R¹³ and R¹⁴ independently represents an aryl group, a benzyl group or an alkyl group having from 1 to 16 carbon atoms; and the alkyl group, the aryl group or the benzyl group may have a hydroxyl group.) (2): R²¹R²²R²³R²⁴N⁺·I⁻ (In formula (2), R²¹, R²², R²³ and R²⁴ may be the same groups or different groups, and each represents an optionally substituted aryl group, benzyl group or alkyl group having from 1 to 10 carbon atoms.)

### TECHNICAL FIELD

The present invention relates to a silicon etching liquid used in an etching step, the silicon etching liquid having high etching speed and high etching selectivity of silicon with respect to silicon-germanium during surface treatment in producing various silicon devices, particularly in producing various silicon composite semiconductor devices containing silicon-germanium. The present invention also relates to a method for producing a silicon device using the above-mentioned etching liquid. The present invention also relates to a method for processing a silicon substrate using the above etching liquid.

### BACKGROUND ART

Silicon etching is used in various steps in semiconductor device production processes. In recent years, treatment processes using silicon have been widely used in a trend where memory cells are multilayered, logic devices are produced three-dimensionally and the like, and smoothness after etching, etching precision, etching selectivity with other materials, and the like have been strongly required on silicon etching used in the treatment processes because of densification of devices. In addition, silicon etching is also applied to processes such as wafer thinning. High integration, refinement, high sensitivity, and high functionality are required on the various silicon devices mentioned above depending on usages, and in order to meet these requirements, silicon etching is considered important as a fine processing technique in the production of these silicon devices. In particular, since variety of silicon composite semiconductor devices containing silicon-germanium are increasing, silicon etching capable of uniformly etching only silicon without dissolving silicon-germanium is considered important.

Silicon etching includes etching with a hydrofluoric acid-nitric acid aqueous solution and etching using alkali. The etching with a hydrofluoric acid-nitric acid aqueous solution is capable of etching isotropically regardless of the crystal orientation of silicon, and capable of uniformly etching silicon single crystal, poly-silicon, and amorphous silicon. However, since the hydrofluoric acid-nitric acid aqueous solution oxidizes silicon to produce a silicon oxide film and etches the silicon oxide film, no etching selection ratio of silicon with respect to the silicon oxide film work. Accordingly, it is difficult to use the hydrofluoric acid-nitric acid aqueous solution in a semiconductor production process in which the silicon oxide film is required to remain, or the like. In addition, since the hydrofluoric acid-nitric acid aqueous solution also dissolves silicon-germanium, it is hard to use the above aqueous solution in a semiconductor production process in which silicon-germanium is required to remain, or the like.

Next, in the case of silicon etching by alkali, because alkali has a high etching selectivity of silicon with respect to a silicon nitride film as well as a high etching selectivity of silicon with respect to a silicon oxide film, alkali can be used in a semiconductor production process in which a silicon oxide film or a silicon nitride film is required to remain. The term “high selectivity” refers to nature indicating a particularly high etching capability for silicon against a specific member. For example, when a substrate having a silicon film of silicon single crystal, poly-silicon or amorphous silicon, and another film (for example, a silicon oxide film) is etched in such a manner that only a silicon film is etched while the silicon oxide film is not etched, the etching selectivity of silicon with respect to the silicon oxide film is considered high. An alkaline etching liquid has a high etching selectivity with respect to a silicon oxide film and a silicon nitride film, and selectively etches a silicon film. As for an alkali-based etching liquid, the etching rate of silicon-germanium is lower than that of silicon, but the selectivity is not sufficient, and therefore it is difficult to etch only the silicon while suppressing the etching of the silicon-germanium film.

As the above-mentioned etching liquid, it is possible to use an aqueous solution of a common alkaline chemical such as KOH, hydrazine, or tetramethylammonium hydroxide (hereinafter also referred to as TMAH) (see Patent Documents 1 and 2). Among the cited chemicals, KOH or TMAH having low toxicity and being easy to handle is preferably used alone. Of the two chemicals, TMAH is more preferably used in consideration of the mixing of metal impurities and the etching selectivity with a silicon oxide film.

With regard to etching using alkali, Patent Document 1 discloses an etching liquid for a silicon substrate for a solar cell, the etching liquid containing alkali hydroxide, water, and polyalkylene oxide alkyl ether. Patent Document 2 discloses an etching liquid for a silicon substrate for a solar cell, the etching liquid containing an alkaline compound, an organic solvent, surfactant, and water. In Patent Document 2, TMAH is exemplified as an example of an alkaline compound, and polyalkylene oxide alkyl ether is exemplified as an organic solvent. However, actually used alkaline compounds are sodium hydroxide and potassium hydroxide. Patent Document 3 discloses a chemical solution in which water, organic alkali, or a water-miscible solvent is optionally mixed with surfactant and a corrosion inhibitor in an etching liquid.

### CITATION LIST

### Patent Documents

Patent Document 1: JP 2010-141139 A
Patent Document 2: JP 2012-227304 A
Patent Document 3: JP 2019-050364 A

### SUMMARY OF INVENTION

### Technical Problem

In the etching liquids of Patent Document 1 and Patent Document 2, NaOH or KOH is used as an alkaline compound. As described above, etching by alkali is high in selectivity with respect to a silicon oxide film compared to a hydrofluoric acid-nitric acid aqueous solution, but the etching rate of the silicon oxide film by alkaline metal hydroxide is high compared to quaternary ammonium hydroxide. Because of this, in the etching of a silicon film, when a silicon oxide film is used for a mask material and part of a pattern structure, even the silicon oxide film that should remain during silicon etching is also etched in a long-time process. Therefore, it is not possible to selectively etch only the silicon film without etching the silicon oxide film. Furthermore, these etching liquids are intended to increase crystal anisotropy and roughen the surface, and therefore the silicon film cannot be smoothly etched. The etching liquid described in Patent Document 3 is a chemical solution capable of selectively removing silicon with respect to silicon-germanium, but does not have sufficient etching selectivity of silicon with respect to silicon-germanium. Further, it is not described in the document to smoothly etch the silicon.

An object of the present invention is to provide a silicon etching liquid having a high etching selectivity of silicon with respect to silicon-germanium, being able to perform processing for suppressing the generation of a hillock on a surface of silicon, and having a high selection ratio with a silicon oxide film during surface treatment in producing various silicon devices, particularly when producing various silicon composite semiconductor devices containing silicon-germanium.

### Solution to Problem

The inventors of the present invention have found, as a result of concentrated research, that the above problems can be solved by using a silicon etching liquid containing a quaternary ammonium hydroxide represented by formula (1), a quaternary ammonium iodide represented by formula (2), and water. The quaternary ammonium hydroxide represented by formula (1) is capable of silicon etching with a high etching selectivity of silicon with respect to a silicon oxide film and a silicon nitride film, and the quaternary ammonium iodide represented by formula (2) is capable of increasing an etching selection ratio of silicon with respect to silicon-germanium.

That is, a first aspect of the present invention relates to a silicon etching liquid comprising a quaternary ammonium hydroxide represented by formula (1), a quaternary ammonium iodide represented by formula (2), and water:

R¹¹R¹²R¹³R¹⁴N⁺·OH⁻ (1)
where R¹¹, R¹², R¹³, and R¹⁴ each independently represents an aryl group, a benzyl group, or an alkyl group having carbon number of 1 to 16, and
the alkyl group, the aryl group, or the benzyl group optionally has a hydroxy group as a substituent;

R²¹R²²R²³R²⁴N⁺·I⁻ (2)
where R²¹, R²², R²³, and R²⁴ each represents alkyl groups having carbon number of 1 to 10 optionally having a substituent, and are optionally the same groups or different groups from each other.

In the first aspect of the present invention, it is preferable that a concentration of the quaternary ammonium hydroxide represented by formula (1) be 0.05 mol/L or more and 1.1 mol/L or less, and the concentration of the quaternary ammonium salt represented by formula (2) be 0.1 mass % or more and 15 mass % or less.

A compound represented by formula (3) can suppress solubility of silicon-germanium, and can more selectively etch silicon with respect to silicon-germanium.

In the first aspect of the present invention, it is further preferable to include a compound represented by formula (3):

R³¹O—(CₘH₂ₘO)ₙ—R³² (3)
where R³¹ represents a hydrogen atom or an alkyl group having carbon number of 1 to 3, R³² represents a hydrogen atom or an alkyl group having carbon number of 1 to 6, m is an integer of 2 to 6, and n is an integer of 1 to 3,
R³¹ and R³² are not hydrogen atoms at the same time, and
in a case of m=2, a total (n+C¹+C²) of n, the carbon number in R³¹ (C¹), and the carbon number in R³² (C²) is five or more.

In the first aspect of the present invention, it is further preferable that a concentration of the compound represented by formula (3) is 0.5 mass % or more and 20 mass % or less.

A polyhydroxy compound having carbon number of 2 to 12 and having two or more hydroxy groups per molecule can reduce a hillock formed in a pyramid shape surrounded by a (111) plane on a silicon surface.

In the first aspect of the present invention, it is further preferable to comprise a polyhydroxy compound having carbon number of 2 to 12 and having two or more hydroxyl groups per molecule.

In the first aspect of the present invention, it is further preferable that a concentration of the polyhydroxy compound is 5 mass % or more and 70 mass % or less.

A quaternary ammonium salt represented by formula (4) can reduce a hillock formed in a pyramid shape surrounded by a (111) plane of a silicon surface.

In the first aspect of the present invention, it is further preferable to comprise a quaternary ammonium salt represented by formula (4):

R⁴¹R⁴²R⁴³R⁴⁴N⁺·X⁻ (4)
where R⁴¹, R⁴², R⁴³, and R⁴⁴ each represents an alkyl group, having carbon number of 1 to 16 and optionally having substituents, and are optionally the same group or different groups from each other, and
X represents BF₄, a fluorine atom, a chlorine atom, or a bromine atom.

In the first aspect of the present invention, it is further preferable that a concentration of the quaternary ammonium salt represented by formula (4) is 1 mass % or more and 50 mass % or less.

A second aspect of the present invention is a method for processing a silicon substrate, the silicon substrate containing at least one silicon material selected from the group consisting of a silicon wafer, a silicon single crystal film, a poly-silicon film, and an amorphous silicon film, the method comprising:
etching the at least one silicon material by using the silicon etching liquid of the first aspect of the present invention.

A third aspect of the present invention is a method for producing a silicon device, the silicon device containing at least one silicon material selected from the group consisting of a silicon wafer, a silicon single crystal film, a poly-silicon film, and an amorphous silicon film, the method comprising:
etching the at least one silicon material by using the silicon etching liquid of the first aspect of the present invention.

### Advantageous Effects of Invention

A silicon etching liquid of the present invention can smoothly etch a surface of a silicon substrate containing at least one silicon material selected from the group consisting of a silicon wafer, a silicon single crystal film, a poly-silicon film, and an amorphous silicon film. In addition, a high selection ratio processing with a silicon oxide film can also be performed, and particularly in a composite semiconductor device containing silicon-germanium, processing with a high etching selectivity of silicon with respect to silicon-germanium may be performed. The costs of toxicity treatment and waste liquid treatment can be reduced because the concentration of a quaternary ammonium hydroxide can be processed even at a low concentration side.

When a polyhydroxy compound or a quaternary ammonium salt represented by formula (4) is further contained, it is possible to suppress the generation of a pyramid-shaped hillock surrounded by a (111) plane on a silicon surface, and perform etching processing smoothly on the silicon surface (100 plane).

### DESCRIPTION OF EMBODIMENTS

Embodiments of the present invention will be described in detail below. However, the descriptions given below are examples (representative examples) of the embodiments of the present invention, and the present invention is not limited to the contents below within the scope and spirit of the invention.

In the present specification, a numerical range represented by using the sign “-” refers to a range including the numerical value described before “-” as the lower limit value and the numerical value described after “-” as the upper limit value, and thus the expression “A-B” means “not smaller than A and not greater than B”.

In the present specification, the expression “optionally the same group or different groups” is expressed as “independently” in some case.

The present invention includes aspects as follows, and the like.

Aspect 1: a silicon etching liquid comprising a quaternary ammonium hydroxide represented by formula (1), a quaternary ammonium iodide represented by formula (2), and water:

R¹¹R¹²R¹³R¹⁴N⁺·OH⁻ (1)
where R¹¹, R¹², R¹³, and R¹⁴ each independently represents an aryl group, a benzyl group, or an alkyl group having carbon number of 1 to 16, and
the alkyl group, the aryl group, or the benzyl group optionally has a hydroxy group as a substituent;

R²¹R²²R²³R²⁴N⁺·I⁻ (2)
where R²¹, R²², R²³, and R²⁴ each represents an aryl group, a benzyl group, or an alkyl group having carbon number of 1 to 10 optionally having a substituent, and are optionally the same groups or different groups from each other.

Aspect 2: the silicon etching liquid according to aspect 1,
wherein a concentration of the quaternary ammonium hydroxide represented by formula (1) is 0.05 mol/L or more and 1.1 mol/L or less, and
a concentration of the quaternary ammonium iodide represented by formula (2) is 0.1 mass % or more and 15 mass % or less.

Aspect 3: the silicon etching liquid according to aspect 1 or 2, further comprising a compound represented by formula (3):

R³¹O—(CₘH₂ₘO)ₙ—R³² (3)
where R³¹ represents a hydrogen atom or an alkyl group having carbon number of 1 to 3, R³² represents a hydrogen atom or an alkyl group having carbon number of 1 to 6, m is an integer of 2 to 6, and n is an integer of 1 to 3,
R³¹ and R³² are not hydrogen atoms at the same time, and
in a case of m=2, a total (n+C¹+C²) of n, the number of carbon number in R³¹ (C¹) and the number of carbon number in R³² (C²) is five or more.

Aspect 4: the silicon etching liquid according to aspect 3,
wherein a concentration of the compound represented by formula (3) is 0.5 mass % or more and 20 mass % or less.

Aspect 5: the silicon etching liquid according to any one of aspects 1 to 4, further comprising a polyhydroxy compound having carbon number of 2 to 12 and having two or more hydroxy groups per molecule.

Aspect 6: the silicon etching liquid according to aspect 5, wherein a concentration of the polyhydroxy compound is 5 mass % or more and 70 mass % or less.

Aspect 7: the silicon etching liquid according to any one of aspects 1 to 6, further comprising a quaternary ammonium salt represented by formula (4):

R⁴¹R⁴²R⁴³R⁴⁴N⁺·X⁻ (4)
where R⁴¹, R⁴², R⁴³, and R⁴⁴ each represents an alkyl group, having carbon number of 1 to 16 and optionally having a substituent, and are optionally the same groups or different groups from each other, and
X represents BF₄, a fluorine atom, a chlorine atom, or a bromine atom.

Aspect 8: the silicon etching liquid according to aspect 7, wherein a concentration of the quaternary ammonium salt represented by formula (4) is 1 mass % or more and 50 mass % or less.

Aspect 9: a method for processing a silicon substrate, the silicon substrate containing at least one silicon material selected from the group consisting of a silicon wafer, a silicon single crystal film, a poly-silicon film, and an amorphous silicon film, the method comprising:
etching the at least one silicon material by using the silicon etching liquid according to any one of aspects 1 to 8.

Aspect 10: a method for producing a silicon device, the silicon device containing at least one silicon material selected from the group consisting of a silicon wafer, a silicon single crystal film, a poly-silicon film, and an amorphous silicon film, the method comprising:
etching the at least one silicon material by using the silicon etching liquid according to any one of aspects 1 to 8.

### Silicon Etching Liquid

A silicon etching liquid of the present invention comprises a quaternary ammonium hydroxide represented by formula (1), a quaternary ammonium iodide represented by formula (2), and water:

R¹¹R¹²R¹³R¹⁴N⁺·OH⁻ (1)
where R¹¹, R¹², R¹³, and R¹⁴ each independently represents an aryl group, a benzyl group, or an alkyl group having carbon number of 1 to 16, and
the alkyl group, the aryl group, or the benzyl group optionally has a hydroxy group as a substituent;

R²¹R²²R²³R²⁴N⁺·I⁻ (2)
where R²¹, R²², R²³, and R²⁴ each represents an aryl group, a benzyl group, or an alkyl group having carbon number of 1 to 10 optionally having a substituent, and are optionally the same group or different groups from each other.

The quaternary ammonium hydroxide represented by formula (1) is capable of silicon etching exhibiting a high etching selectivity of silicon with respect to a silicon oxide film and a silicon nitride film, and the quaternary ammonium iodide represented by formula (2) is capable of increasing an etching selection ratio of silicon with respect to silicon-germanium.

In the present invention, it is preferable that a concentration of the quaternary ammonium hydroxide represented by formula (1) is 0.05 mol/L or more and 1.1 mol/L or less, and a concentration of the quaternary ammonium salt represented by formula (2) is 0.1 mass % or more and 50 mass % or less.

In the quaternary ammonium hydroxide represented by formula (1), R¹¹, R¹², R¹³, and RH each represents an alkyl group, an aryl group, or a benzyl group optionally having a substituent, and are optionally the same group or of different groups. The alkyl group, the aryl group, or the benzyl group optionally has a hydroxy group as a substituent.

As the alkyl group, such an alkyl group is preferred that an alkyl group having carbon number of 1 to 16 contained in each of R¹¹, R¹², R¹³, and R¹⁴, and an alkyl group having carbon number of 1 to 4 is more preferred. As the aryl group, an aryl group having carbon number of 6 to 10 is preferred, and as the benzyl group, a benzyl group having carbon number of 7 to 10 is preferred.

The alkyl group, aryl group, and benzyl group can include a hydroxy group as a substituent in order to improve solubility into water.

Examples of R¹¹, R¹², R¹³, and R¹⁴ can include an unsubstituted alkyl group having carbon number of 1 to 4, such as a methyl group, ethyl group, n-propyl group, i-propyl group, n-butyl group, i-butyl group, sec-butyl group, or tert-butyl group; an alkyl group having carbon number of 1 to 4 and substituted with a hydroxy group, such as a hydroxymethyl group, hydroxyethyl group, hydroxy-n-propyl group, hydroxy-i-propyl group, hydroxy-n-butyl group, hydroxy-i-butyl group, hydroxy-sec-butyl group, or hydroxy-tert-butyl group; a phenyl group; a tolyl group; an o-xylyl group; and a benzyl group.

A total of carbon number in R¹¹, R¹², R¹³, and R¹⁴ is preferably 20 or less from the perspective of solubility; R¹¹, R¹², R¹³, and R¹⁴ are preferably alkyl groups having carbon number of 1 to 4 or alkyl groups having carbon number of 1 to 4 and substituted with a hydroxy group, and at least three of R¹¹, R¹², R¹³, and R¹⁴ are preferably of the same alkyl group. It is preferable that the alkyl group has carbon number of 1 to 4 is methyl, ethyl, propyl, a butyl group, an isobutyl group, or a hydroxyethyl group, and that the at least three same alkyl groups are trimethyl, triethyl, or tributyl.

Examples of the quaternary ammonium hydroxide represented by formula (1) can include tetramethylammonium hydroxide (TMAH), tetraethylammonium hydroxide (TEAH), ethyltrimethylammonium hydroxide (ETMAH), tetrapropylammonium hydroxide (TPAH), tetrabutylammonium hydroxide (TBAH), trimethyl-2-hydroxyethylammonium hydroxide (choline hydroxide), dimethylbis (2-hydroxyethyl) ammonium hydroxide, methyltris (2-hydroxyethyl) ammonium hydroxide, trimethylphenylammonium hydroxide, and benzyltrimethylammonium hydroxide. Among these, TMAH, choline hydroxide, TEAH, ETMAH, TPAH, or TBAH can be preferably used. In particular, it is most preferable to use TMAH, choline hydroxide, ETMAH, TEAH, or TPAH because of a high etching rate of silicon.

As the concentration of the quaternary ammonium hydroxide represented by formula (1) in the silicon etching liquid, the concentration of a silicon etching liquid of related art can be applied similarly, and when the concentration is 0.05 mol/L or more and 1.1 mol/L or less, an excellent etching effect is preferably obtained without the occurrence of crystal precipitation. It is more preferable for the concentration of the quaternary ammonium hydroxide to be 0.05 mol/L or more and 0.6 mol/L or less.

One type of quaternary ammonium represented by formula (1) can be used alone, or a plurality of different types thereof can be mixed and used.

The silicon etching liquid of the present invention comprises the quaternary ammonium iodide represented by formula (2). Containing the quaternary ammonium iodide represented by formula (2) enables the solubility of silicon-germanium to be suppressed without reducing the solubility of silicon, and thus silicon can be selectively etched with respect to silicon-germanium. At this time, the silicon etching selection ratio (etching rate ratio) with respect to silicon-germanium is preferably not less than 90, and more preferably not less than 100.

A mechanism that makes it possible for the quaternary ammonium iodide represented by formula (2) to increase the etching selection ratio of silicon with respect to silicon-germanium is not necessarily apparent. However, the inventors of the present invention consider the mechanism as follows.

Iodine ions contained in the quaternary ammonium iodide represented by formula (2) are highly nucleophilic compared to chloride ions, bromide ions, or the like as other anions, and are more nucleophilic than hydroxide ions contained in the silicon etching liquid. Thus, it is conceivable that, at the time of etching, iodine ions are preferentially bonded to silicon and germanium on the surface of the etching target substrate compared to hydroxide ions, and silicon-iodine and germanium-iodine are respectively produced.

Further, since the iodine ion is excellent not only as a nucleophilic reagent but also as a leaving group, it is conceivable that the silicon-iodine and germanium-iodine each react with hydroxide ions in the etching liquid, then the iodine ions are separated, and the etching progresses by producing silicon hydroxide and germanium hydroxide. The inventors of the present invention consider that, because silicon is less electronegative than germanium, the iodine ion is more likely to bond to silicon than to germanium, and the rate of silicon at which the etching progresses through hydroxide is faster than the rate of germanium, so that the silicon can be selectively etched with respective to the silicon-germanium.

In the quaternary ammonium iodide represented by formula (2), R²¹, R²², R²³, and R²⁴ each represents an alkyl group, an aryl group, or a benzyl group optionally having a substituent, and are optionally the same groups or different groups. As the alkyl group, such an alkyl group is preferred that an alkyl group has carbon number of 1 to 10 contained in each of R²¹, R²², R²³, and R²⁴, and an alkyl group having carbon number of 1 to 4 is more preferred from the perspective of solubility into water and effects. As the aryl group, an aryl group having carbon number of 6 to 10 is preferred, and as the benzyl group, a benzyl group having carbon number of 7 to 10 is preferred. Substituents that an alkyl group, aryl group, or benzyl group can include are not particularly limited, and examples of the substituents include a halogenyl group, a hydroxy group, an alkoxy group having carbon number of 1 to 20, —C≡N, —NH₃, —C(═O)OH, —C(═O)OR′, —C(═O)R′, —SH, —SiR^{a}R^{b}R^{c}, —BH₂, —SeH, a monovalent aromatic hydrocarbon cyclic group, and a monovalent aromatic heterocyclic group. R′, R^{a}, R^{b}, and R^{c} can each independently represent hydrogen or an alkyl group having carbon number of 1 to 20, and can particularly include a hydroxy group as a substituent.

Examples of R²¹, R²², R²³, and R²⁴ can include an unsubstituted alkyl group having carbon number of 1 to 16, such as a methyl group, ethyl group, n-propyl group, i-propyl group, n-butyl group, i-butyl group, sec-butyl group, tert-butyl group, hexyl group, octyl group, decyl group, dodecyl group, tetradecyl group, or hexadecyl group; an alkyl group having carbon number of 1 to 4 and substituted with a hydroxy group, such as a hydroxymethyl group, hydroxyethyl group, hydroxy-n-propyl group, hydroxy-i-propyl group, hydroxy-n-butyl group, hydroxy-i-butyl group, hydroxy-sec-butyl group, or hydroxy-tert-butyl group, a phenyl group; a tolyl group; an o-xylyl group; and a benzyl group.

Here, all of R²¹, R²², R²³, and R²⁴ can be the same groups or different groups.

Specific examples of the quaternary ammonium iodide represented by formula (2) include tetramethylammonium iodide, tetraethylammonium iodide, tetrapropylammonium iodide, tetrabutylammonium iodide, ethyltrimethylammonium iodide, butyltrimethylammonium iodide, hexyltrimethylammonium iodide, octyltrimethylammonium iodide, decyltrimethylammonium iodide, phenyltrimethylammonium iodide, and benzyltrimethylammonium iodide. It is preferable that at least one of R²¹, R²², R²³, and R²⁴ is a different group from the perspective of water solubility. It is more preferable that at least one of groups of R²¹, R²², R²³, and R²⁴ is an aryl group, a benzyl group, or an alkyl group having carbon number of 1 to 4.

Specific examples of the preferably used quaternary ammonium iodide represented by formula (2) include butyltrimethylammonium iodide, hexyltrimethylammonium iodide, octyltrimethylammonium iodide, decyltrimethylammonium iodide, phenyltrimethylammonium iodide, and benzyltrimethylammonium iodide.

One type of quaternary ammonium iodide represented by formula (2) can be used alone, or a plurality of different types thereof can be mixed and used.

Quaternary ammonium cations of the quaternary ammonium hydroxide represented by formula (1) and the quaternary ammonium iodide represented by formula (2) can be the same.

The concentration of the quaternary ammonium iodide represented by formula (2) is not particularly limited, but it is preferable for the concentration thereof to be 0.1 mass % or more and 15 mass % or less, and more preferable to be 0.1 mass % or more and 10 mass % or less because the solubility of silicon-germanium is suppressed without decreasing the solubility of silicon, and the silicon can be selectively etched with respect to the silicon-germanium.

The silicon etching liquid of the present invention can further comprise the compound represented by formula (3). Containing the compound represented by formula (3) enables the solubility of silicon-germanium to be suppressed, and thus silicon can be more selectively etched with respect to the silicon-germanium. It is conceivable that, like the compound represented by formula (3), a glycol ether compound having both sufficient solubility to water and an appropriate hydrophobic group is more preferentially adsorbed to germanium than to silicon so as to suppress the separation of germanium-iodine.

The silicon etching liquid of the present invention further comprises at least one compound selected from the compounds represented by formula (3):

R³¹O—(CₘH₂ₘO)ₙ—R³² (3)
where R³¹ represents a hydrogen atom or an alkyl group having carbon number of 1 to 3, R³² represents a hydrogen atom or an alkyl group having carbon number of 1 to 6, m is an integer of 2 to 6, and n is an integer of 1 to 3,
R³¹ and R³² are not hydrogen atoms at the same time, and in a case of m=2, a total (n+C¹+C²) of n, the carbon number in R³¹ (C¹), and the carbon number in R³² (C²) is five or more.

A hydrogen atom or a methyl group is preferred as R³¹, a propyl group or butyl group is preferred as R³², and m is preferably 2 or 3.

Specific examples of the compound represented by formula (3) that is particularly preferably used in the present invention can include ethylene glycol monobutyl ether, diethylene glycol ethyl methyl ether, diethylene glycol diethyl ether, diethylene glycol monobutyl ether, propylene glycol monomethyl ether, propylene glycol monoethyl ether, propylene glycol monopropyl ether, propylene glycol monobutyl ether, propylene glycol dimethyl ether, dipropylene glycol monomethyl ether, dipropylene glycol monopropyl ether, dipropylene glycol dimethyl ether, triethylene glycol monobutyl ether, and tripropylene glycol monomethyl ether. Among these, ethylene glycol monobutyl ether, diethylene glycol monobutyl ether, propylene glycol monoethyl ether, propylene glycol monopropyl ether, propylene glycol monobutyl ether, dipropylene glycol monopropyl ether, triethylene glycol monobutyl ether and tripropylene glycol monomethyl ether are preferred, and diethylene glycol monobutyl ether, propylene glycol monopropyl ether, and triethylene glycol monobutyl ether are more preferred.

One type of compound represented by formula (3) can be used alone, or a plurality of different types thereof can be mixed and used.

The concentration of at least one compound selected from the compounds represented by formula (3) is preferably 0.5 mass % or more and 20 mass % or less, more preferably less than 15 mass %, and further more preferably less than 10 mass %, based on the mass of the whole etching liquid.

The silicon etching liquid of the present invention can further comprise a polyhydroxy compound having carbon number of 2 to 12 and having two or more hydroxy groups per molecule (hereinafter also referred to simply as a polyhydroxy compound). Containing the polyhydroxy compound enables suppressing of the occurrence of a pyramid-shaped hillock surrounded by the (111) plane on the silicon surface, and smooth etching of the silicon surface without causing roughness on the silicon surface.

In the polyhydroxy compound, carbon number is not less than 2 and not more than 12, and is preferably not less than 2 and not more than 6.

The ratio of the number of hydroxy groups to the number of carbon atoms in a molecule of the polyhydroxy compound (OH/C) is preferably 0.3 or more, more preferably 0.4 or more, and further more preferably 0.5 or more from the perspective of performing smooth etching on the silicon because hydration progresses due to hydrogen bonding between the hydroxy group and water, and free water molecules that contribute to the reaction decrease.

Specific examples of the polyhydroxy compound preferably used in the present invention include ethylene glycol, propylene glycol, 1,3-propanediol, 1,2-butanediol, 1,3-butanediol, 1,4-butanediol, 1,5-pentanediol, 1,2-hexanediol, 1,6-hexanediol, hexylene glycol, cyclohexanediol, pinacol, glycerin, trimethylolpropane, erythritol, pentaerythritol, dipentaerythritol, and diglycerol. Among these, ethylene glycol, pentaerythritol, glycerin, or diglycerol is preferred.

The concentration of the polyhydroxy compound is preferably 5 mass % or more and 70 mass % or less, and more preferably 10 mass % or more and 60 mass % or less based on the mass of the whole silicon etching liquid.

One type of polyhydroxy compound can be used alone, or a plurality of different types thereof can be mixed and used.

The silicon etching liquid of the present invention can further comprise a quaternary ammonium salt represented by formula (4). Containing the quaternary ammonium salt represented by formula (4) enables suppressing of the occurrence of a pyramid-shaped hillock surrounded by the (111) plane on the silicon surface, and smooth etching without causing roughness on the silicon surface.

R⁴¹R⁴²R⁴³R⁴⁴N⁺·X⁻ (4)

In the formula, R⁴¹, R⁴², R⁴³, and R⁴⁴ each represents alkyl groups, having carbon number of 1 to 16 and optionally having a substituent, and are optionally the same groups or different groups, and
X represents BF₄, a fluorine atom, a chlorine atom, or a bromine atom.

In the quaternary ammonium salt represented by formula (4), R⁴¹, R⁴², R⁴³, and R⁴⁴ each represents an alkyl group, having carbon number of 1 to 16 and optionally having a substituent, and are optionally the same groups or different groups.

Substituents that the above alkyl groups can include are not particularly limited, and examples of the substituents include a halogenyl group, a hydroxy group, an alkoxy group having carbon number of 1 to 20, —C≡N, —NH₃, —C(═O)OH, —C(═O)OR′, —C(═O)R′, —SH, —SiR^{a}R^{b}R^{c}, —BH₂, —SeH, a monovalent aromatic hydrocarbon cyclic group, and a monovalent aromatic heterocyclic group. R′, R^{a}, R^{b}, and R^{c} can each represent hydrogen or an alkyl group having carbon number of 1 to 20, and are optionally the same groups or different groups. In particular, as a substituent, the hydroxy group is preferred because of excellent solubility into water.

Examples of R⁴¹, R⁴², R⁴³, and R⁴⁴ can include an unsubstituted alkyl group having carbon number of 1 to 16, such as a methyl group, ethyl group, n-propyl group, i-propyl group, n-butyl group, i-butyl group, sec-butyl group, tert-butyl group, hexyl group, octyl group, decyl group, dodecyl group, tetradecyl group, and hexadecyl group; and an alkyl group having carbon number of 1 to 4 and substituted with a hydroxy group, such as a hydroxymethyl group, hydroxyethyl group, hydroxy-n-propyl group, hydroxy-i-propyl group, hydroxy-n-butyl group, hydroxy-i-butyl group, hydroxy-sec-butyl group, and hydroxy-tert-butyl group.

The total number of carbon atoms in a molecule of the quaternary ammonium salt represented by formula (4) is preferably 4 or more and 20 or less, and more preferably 9 or more and 15 or less, from the perspective of the solubility into water and the capability of performing smooth etching on the silicon surface; furthermore, it is particularly preferable for the total number thereof to be 9 or more and 13 or less from the perspective of the silicon etching rate.

All of R⁴¹, R⁴², R⁴³, and R⁴⁴ can be the same groups, but it is preferable that at least one of them be a different group. More preferably, at least one of the groups of R⁴¹, R⁴², R⁴³, and R⁴⁴ is an alkyl group having carbon number of 2 to 16, and the remainder groups are alkyl groups having carbon number of 1 to 4; further preferably, the remainder groups are alkyl groups having carbon number of 1 to 2; particularly preferably, the remainder groups are alkyl groups having carbon number of 1; and most preferably, the remainder groups are methyl groups having carbon number of 1.

X represents BF₄, a fluorine atom, a chlorine atom or a bromine atom, and preferably represents a chlorine atom or a bromine atom.

Specific examples of the quaternary ammonium salt represented by formula (4) preferably used in the present invention include tetramethylammonium salt, tetraethylammonium salt, tetrapropylammonium salt, tetrabutylammonium salt, ethyltrimethylammonium salt, butyltrimethylammonium salt, hexyltrimethylammonium salt, octyltrimethylammonium salt, decyltrimethylammonium salt, dodecyltrimethylammonium salt, tetradecyltrimethylammonium salt, and hexadecyltrimethylammonium salt. Among these, octyltrimethylammonium salt, decyltrimethylammonium salt, dodecyltrimethylammonium salt, tetradecyltrimethylammonium salt and hexadecyltrimethylammonium salt are further preferred, and octyltrimethylammonium salt, decyltrimethylammonium salt, or dodecyltrimethylammonium salt may be used preferably.

One type of quaternary ammonium salt represented by formula (4) can be used alone, or a plurality of different types thereof can be mixed and used.

In the quaternary ammonium hydroxide represented by formula (1) and/or the quaternary ammonium iodide represented by formula (2) and/or the quaternary ammonium salt represented by formula (4), the quaternary ammonium cations represented by the above formulae can be the same.

For example, when the cation of the quaternary ammonium hydroxide represented by formula (1) and the cation of the quaternary ammonium salt represented by formula (4) are identical, the concentration of the quaternary ammonium cations of the quaternary ammonium salt represented by formula (4) can be calculated from the concentration of anions of the quaternary ammonium salt represented by formula (4). Specifically, the concentrations of the anions and the cations are equivalent to each other in a molar ratio, and furthermore, from the concentration of the above cations, the concentration of the quaternary ammonium cations of the quaternary ammonium hydroxide represented by formula (1) can be calculated. That is, the concentration of the cations constituting the quaternary ammonium hydroxide represented by formula (1) is a concentration obtained by subtracting the quaternary ammonium cations represented by formula (4) from the quaternary ammonium cation concentration of the whole etching liquid.

In the present embodiment, the silicon etching liquid can be treated considering that the quaternary ammonium hydroxide represented by formula (1), the quaternary ammonium iodide represented by formula (2), and the quaternary ammonium salt represented by formula (4) are contained, in a case where the cations and anions constituting the quaternary ammonium hydroxide represented formula (1), the cations and anions constituting the quaternary ammonium iodide represented by formula (2), and the cations and anions constituting the quaternary ammonium salt represented by formula (4) are contained.

Such a method can be used not only when the quaternary ammonium cations represented by formula (1) and formula (4) are identical, but also when some or all of the quaternary ammonium cations represented by formula (1), formula (2), and formula (4) are identical.

The concentration of the quaternary ammonium salt represented by formula (4) in the silicon etching liquid is not particularly limited. However, it is preferable for the concentration thereof to be 1 mass % or more and 50 mass % or less, more preferable to be 1 mass % or more and 35 mass % or less, further preferable to be 1 mass % or more and 20 mass % or less, and particularly preferable to be 1 mass % or more and 15 mass % or less, and it is preferable for the lower limit of the concentration to be not less than 1.5 mass %, because doing so enables smooth etching without causing roughness on the silicon surface even when the concentration of the quaternary ammonium hydroxide represented by formula (1) is low, specifically, the reduction in surface roughness of the 100 plane of the silicon and the suppression of a pyramid-shaped hillock surrounded by the 111 plane enables smooth etching.

In the silicon etching liquid, the ratio of the concentration of the quaternary ammonium salt represented by formula (2) to the concentration of the quaternary ammonium hydroxide represented by formula (1) (formula (2)/formula (1)) is not particularly limited. However, because an deficient addition of the quaternary ammonium salt represented by formula (2) makes it difficult to perform smooth etching, and an excessive addition of the quaternary ammonium salt represented by formula (2) causes a reduction in the etching rate, the ratio thereof, in terms of a molar ratio, is typically in a range of 0.02 to 5.00, preferably in a range of 0.03 to 2.50, and more preferably in a range of 0.04 to 0.75.

The silicon etching liquid of the present invention can include each of the compound represented by formula (3), polyhydroxy compound, and the quaternary ammonium salt represented by formula (4) alone, or can include a combination thereof.

A form of water in the silicon etching liquid is not particularly limited, and known water can optionally be used; it is particularly preferable that the water be ultrapure water in which metal impurities are reduced. The content of the water in the silicon etching liquid is not particularly limited, and is typically 10 mass % or more, preferably 20 mass % or more, and more preferably 30 mass % or more; further, the content thereof is 95 mass % or less, preferably 90 mass % or less, and more preferably 70 mass % or less.

Without departing from the object of the present invention, a surfactant or the like can be added to the silicon etching liquid, aside from the compound represented by formula (3), the polyhydroxy compound, and/or the quaternary ammonium salt represented by formula (4), which are optionally added in addition to the quaternary ammonium hydroxide represented by formula (1) and the quaternary ammonium iodide represented by formula (2). However, the silicon etching liquid substantially consists of the quaternary ammonium hydroxide represented by formula (1), the quaternary ammonium salt represented by formula (2) and water, as well as the compound represented by formula (3), the polyhydroxy compound, and/or the quaternary ammonium salt represented by formula (4), which are optionally and additionally added, and it is preferable that the content of other components than the above-mentioned ones such as a surfactant be not more than 1 mass %, and is more preferable that the other components be not contained (the content thereof is below the detection limit). In other words, it is preferable that all of the remainder of the silicon etching liquid excluding the quaternary ammonium hydroxide represented by formula (1) and the quaternary ammonium iodide represented by formula (2) as well as the compound represented by formula (3), the polyhydroxy compound, and/or the quaternary ammonium salt represented by formula (4) is water.

In order to increase the smoothness of the silicon surface, it is important, by using the polyhydroxy compound and/or the quaternary ammonium salt represented by formula (4) in the silicon etching liquid, to cause the etching selection ratio of the 100 plane and the 111 plane of the silicon (100/111) to approach 1, and the smoothness is improved when the etching selection ratio is not more than 3.2, preferably not more than 2.8, and more preferably not more than 2.5.

In the silicon etching liquid, the quaternary ammonium hydroxide represented by formula (1) and/or the quaternary ammonium iodide represented by formula (2) and/or the quaternary ammonium salt represented by formula (4) are ionized and dissociated into quaternary ammonium cations represented by formula (1′) and OH⁻, quaternary ammonium cations represented by formula (2′) and I⁻, and quaternary ammonium cations represented by formula (4′) and X.

R¹¹R¹²R¹³R¹⁴N⁺ (1′)

In formula (1′), R¹², R¹³, and R¹⁴ have the same meanings as those in formula (1).

R²¹R²²R²³R²⁴N⁺ (2′)

In formula (2′), R²¹, R²², R²³, and R²⁴ have the same meanings as those in formula (2).

R⁴¹R⁴²R⁴³R⁴⁴N⁺ (4′)

In formula (4′), R⁴¹, R⁴², R⁴³, and R⁴⁴ have the same meanings as those in formula (4) described above.

Accordingly, a silicon etching liquid containing these ionic species (1′) and (2′) is the silicon etching liquid of the present invention. In addition, a silicon etching liquid further containing an ionic species (4′) is also one aspect of the silicon etching liquid of the present invention. The quaternary ammonium hydroxide represented by formula (1) and/or the quaternary ammonium iodide represented by formula (2) and/or the quaternary ammonium salt represented by formula (4) can reside in a silicon etching liquid due to anion exchanges carried out in any combination. For example, in a silicon etching liquid containing the quaternary ammonium hydroxide represented by formula (1) and the quaternary ammonium iodide represented by formula (2), there can be salts consisting of the quaternary ammonium cations represented by formula (1′) and I⁻, and salts consisting of the quaternary ammonium cations represented by formula (2′) and OH⁻ by anion exchange.

At this time, it goes without saying that the concentration of the quaternary ammonium cations represented by formula (1′) is the same as that of the quaternary ammonium hydroxide represented by formula (1), the concentration of the quaternary ammonium cations represented by formula (2′) and I⁻ is the same as that of the quaternary ammonium salt represented by formula (2), and the concentration of the quaternary ammonium cations represented by formula (4′) and X⁻ is the same as that of the quaternary ammonium salt represented by formula (4). The composition of the silicon etching liquid of the present invention can be confirmed by analyzing and quantifying the ionic components and the concentration thereof in the silicon etching liquid, and converting the resultants to the quaternary ammonium hydroxide represented by formula (1), the quaternary ammonium iodide represented by formula (2), and the quaternary ammonium salt represented by formula (4). Quaternary ammonium cations can be measured by liquid chromatography or ion chromatography, OH⁻ ions may be measured by neutralization titration, and X⁻ ions may be measured by ion chromatography.

Method for Producing Silicon Etching Liquid

A method for producing the silicon etching liquid of the present invention is not particularly limited. It is sufficient that the quaternary ammonium hydroxide represented by formula (1) and the quaternary ammonium iodide represented by formula (2), and/or the compound represented by formula (3) and/or the polyhydroxy compound and/or the quaternary ammonium salt represented by formula (4) are mixed with water to have a predetermined concentration, and these components are dissolved in the water. The quaternary ammonium hydroxide represented by formula (1) and the quaternary ammonium iodide represented by formula (2), and/or the compound represented by formula (3) and/or the polyhydroxy compound and/or formula (4) can be used as it is, or can each be used as an aqueous solution.

The silicon etching liquid of the present invention can also be produced by using a quaternary ammonium hydroxide represented by formula (2-1) and a quaternary ammonium hydroxide represented by formula (2-2) in place of the quaternary ammonium iodide represented by formula (2) and the quaternary ammonium salt represented by formula (4) to prepare an aqueous solution containing the quaternary ammonium hydroxide represented by formula (1) and the quaternary ammonium hydroxide represented by formula (2-1) and formula (2-2), and then adding a suitable amount of acid represented by HI and HX (X has the same meaning as that in formula (2)) to the aqueous solution.

R²¹R²²R²³R²⁴N⁺·OH⁻ (2-1)

In formula (2-1), R²¹, R²², R²³, and R²⁴ have the same meanings as those in formula (2).

R⁴¹R⁴²R⁴³R⁴⁴N⁺·OH⁻ (2-2)

In formula (2-2), R⁴¹, R⁴², R⁴³, and R⁴⁴ have the same meanings as those in formula (4).

The silicon etching liquid of the present invention can be used in a method for processing a silicon substrate. A method for processing a silicon substrate of another embodiment of the present invention is a method for processing a silicon substrate, the silicon substrate containing at least one silicon material selected from the group consisting of a silicon wafer, a silicon single crystal film, a poly-silicon film, and an amorphous silicon film, the method including etching the at least one silicon material by using the above-described silicon etching liquid. In particular, the method can be suitably used for processing various silicon composite semiconductor devices containing silicon-germanium. The silicon single crystal film includes a film fabricated by epitaxial growth, and the silicon single crystal film, poly-silicon film, and amorphous silicon film can be collectively referred to as a silicon film.

Accordingly, the silicon etching liquid described above can suitably be used in a method for producing a silicon device. A method for producing a silicon device of another embodiment of the present invention is a method for producing a silicon device, the silicon device containing at least one silicon material selected from the group consisting of a silicon wafer, a silicon single crystal film, a poly-silicon film, and an amorphous silicon film, the method including etching the at least one silicon material by using the above-described silicon etching liquid.

An etching method in the etching step of each of the processing method for the silicon substrate and the production method for the silicon device is not particularly limited except that the silicon etching liquid described above is used, and can be carried out by a known method; for example, a method to be explained in the description of wet etching can be cited.

The processing method for the silicon substrate and the production method for the silicon device can each include a step other than the etching step, for example, a step of preparing an etching target.

In the present specification, the silicon wafer, silicon single crystal film, poly-silicon film, and amorphous silicon film are collectively referred to as a silicon material.

The substrate is a designation during the silicon device production process, and is also referred to as a silicon substrate in the specification of the present application.

A method for processing a substrate according to a first embodiment using the silicon etching liquid of the present invention includes,
holding the substrate in a horizontal posture, and
supplying an isotropic silicon etching liquid of the present invention onto a principal surface of the substrate while rotating the substrate about a vertical rotation axis line passing through a central portion of the substrate.

A method for processing a substrate according to a second embodiment using the silicon etching liquid of the present invention includes,
holding a plurality of substrates in an upright posture, and
immersing each of the plurality of substrates in the upright posture in the isotropic etching liquid of the present invention stored in a processing tank.

In a preferred embodiment of the present invention, the silicon etching liquid can be used in a silicon device production including a step of supplying the silicon etching liquid and smoothly etching a silicon material contained in the silicon substrate.

In consideration of the desired etching rate, the shape of the silicon after etching, the surface state, the productivity, or the like, the temperature of the silicon etching liquid during etching according to each of the above embodiments can be determined as appropriate in a range of 20° C. or higher and 95° C. or less, and preferably determined in a range of 40° C. or higher and 90° C. or less.

It is sufficient that wet etching of the silicon material only immerses an object to be etched in the silicon etching liquid, but it is also possible to employ an electrochemical etching method that applies a constant potential to the object to be etched such as an anodic oxidation method that applies a positive voltage after the immersion of the silicon material in the silicon etching liquid.

Examples of target objects of the etching processing of the present invention include silicon single crystal, poly-silicon, and amorphous silicon; films of non-target objects that are not the targets of the etching processing, such as a silicon oxide film, a silicon nitride film, a silicon-germanium film, and various metal films (for example, an aluminum film), can be contained in the target objects, or a metal such as aluminum can be contained therein. For example, an object formed in a patterning shape obtained by laminating a silicon oxide film, a silicon nitride film, a silicon-germanium film, and a metal film on silicon single crystal, an object where silicon or poly-silicon is deposited on the above-mentioned object, a structure in which silicon is subjected to pattern formation, and the like can be cited.

### EXAMPLES

Hereinafter, the present invention will be described more specifically based on examples, but the present invention is not limited to the examples below.

### Example 1

A silicon etching liquid of a composition depicted in Table 1 was prepared, in which tetramethylammonium hydroxide (TMAH) was used as the quaternary ammonium hydroxide represented by formula (1), ethyltrimethylammonium iodide was used as the quaternary ammonium iodide represented by formula (2), and the remainder was water.

### <Evaluation Method of Etching Selection Ratio of Silicon Single Crystal Substrates (100 Plane) and (111 Plane)>

A silicon single crystal substrate (100 plane) having a size of 2 cm×2 cm was immersed in a silicon etching liquid heated to a liquid temperature described in Table 2 for 10 minutes when the liquid temperature was 60° C. or 60 minutes when 40° C., and then the etching rate of the silicon single crystal at each temperature was measured. A natural oxide film of the silicon single crystal substrate to be examined was removed by a chemical solution. The weights of the silicon single crystal substrate (100 plane) before and after the etching of the silicon single crystal substrate were measured, an etching amount of the silicon single crystal substrate was calculated using a difference between the weights before and after the etching processing, and then the etching amount was divided by the etching time to determine an etching rate (R₁₀₀). Likewise, a silicon single crystal substrate (111 plane) having a size of 2 cm×2 cm was immersed for 120 minutes, an etching rate (R₁₁₁) of the silicon single crystal at the liquid temperature was measured, and then an etching selection ratio (R₁₀₀/R₁₁₁) with the silicon single crystal substrate (100 plane) was determined.

### <Evaluation Method of Surface Roughness of Silicon Single Crystal Substrate (100 Plane)>

Under the same conditions as those of the etching of the silicon single crystal substrate (100 Plane) in the section “Evaluation Method of Etching Selection Ratio of Silicon Single Crystal Substrates (100 Plane) and (111 Plane)”, the etching was carried out to obtain an etching amount of approximately 1 μm; thereafter, the surface state of the silicon single crystal substrate (100 plane) was observed visually and observed with a field emission scanning electron microscope (FE-SEM), and the observation results were evaluated based on criteria described below. Table 2 depicts the results.

### <Evaluation Criteria for Surface Roughness of Silicon Single Crystal Substrate (100 Plane)>

### (Visual Observation Result)

5: The wafer surface is not cloudy at all, and is specular.
3: The wafer surface is slightly cloudy, but is specular.
1: The wafer surface is completely cloudy, but is still specular to some extent.
0: The wafer surface is completely cloudy, and is not specular due to severe surface roughness.

### (FE-SEM Observation Result)

Three optional locations were selected and each location was observed at a twenty-thousand magnification, where an area of 50 μm square was observed to check the presence or absence of a hillock.
5: No hillock is observed on the entire surface of the evaluation substrate.
3: A small number of minute hillocks are observed on the evaluation substrate.
0: A large number of hillocks are observed on the evaluation substrate.
   <Evaluation of Selection Ratio of Silicon Single Crystal (100 Plane) and Silicon-Germanium Film, Silicon Oxide film, and Silicon Nitride Film>

A silicon-germanium film having a size of 2 cm×2 cm, a silicon oxide film, and a silicon nitride film having a size of 2 cm×2 cm were immersed in a silicon etching liquid heated to the liquid temperature described in Table 2 for 10 minutes, and then the etching rates of the silicon-germanium film, the silicon oxide film, and the silicon nitride film at each temperature were measured. The film thicknesses of the silicon-germanium film, the silicon oxide film, and the silicon nitride film before and after etching were measured with a spectroscopic ellipsometer, the etching amounts of the silicon-germanium film, the silicon oxide film, and the silicon nitride film were calculated using the film thickness differences before and after the etching processing, and then each etching amount was divided by the etching time to determine the etching rate. Next, etching selection ratios (R₁₀₀/R_{siGe}), (R₁₀₀/silicon oxide film), and (R₁₀₀/silicon nitride film) with the silicon single crystal substrate (100 plane) were calculated. (R₁₀₀/silicon oxide film) and (R₁₀₀/silicon nitride film) were evaluated based on criteria described below. Table 2 depicts the results.

<Evaluation Criteria for Selection Ratio of Silicon Single Crystal and Silicon Oxide Film as well as Silicon Nitride Film>

Evaluation criteria for a selection ratio of silicon and a silicon oxide film (Si (100 plane)/SiO₂):
A: 1000 or more; B: 700 or more and less than 1000; C: 500 or more and less than 700; D: less than 500

Evaluation criteria for a selection ratio of silicon single crystal and a silicon nitride film (Si (100 plane)/SiN):
A: 1000 or more; B: 700 or more and less than 1000; C: 500 or more and less than 700; D: less than 500

In the above evaluations, the etching selection ratios greater than or equal to B were considered to exhibit favorable selectivity.

### Examples 2 to 20

Properties of the examples were evaluated in a similar manner to that of Example 1 except that silicon etching liquids having the composition depicted in Table 1 were used as the silicon etching liquids, and etching was carried out at the temperatures depicted in table 2. Evaluation results are depicted in Table 2.

### Comparative Examples 1 to 11

Properties of the comparative examples were evaluated in a similar manner to that of Example 1 except that silicon etching liquids having the composition depicted in Table 1 were used as the silicon etching liquids. Evaluation results are depicted in Table 2.

TABLE 1

| | Silicon Etching Liquid | | | | | |
|---|---|---|---|---|---|---|
| | Quaternary | | Quaternary | | | |
| | ammonium | | ammonium | | | |
| | hydroxide | | salt | | | |
| | (Compound | | (Compound | | Compound | |
| | represented | Content | represented | Content | represented | Content |
| | by formula (1)) | (mol/L) | by formula (2)) | (wt. %) | by formula(3) | (wt. %) |
| Example 1 | TMAH | 0.26 | Ethyltrimethyl | 5 | — | — |
| | | | ammonium iodide | | | |
| Example 2 | TMAH | 0.26 | Ethyltrimethyl | 5 | Triethylene glycol | 2 |
| | | | ammonium iodide | | monobutyl ether | |
| Example 3 | TMAH | 0.26 | Ethyltrimethyl | 5 | — | — |
| | | | ammonium iodide | | | |
| Example 4 | TMAH | 0.26 | Ethyltrimethyl | 1 | Triethylene glycol | 1 |
| | | | ammonium iodide | | monobutyl ether | |
| Example 5 | TMAH | 0.26 | Phenyltrimethyl | 5 | Propylene glycol | 1 |
| | | | ammonium iodide | | monopropyl ether | |
| Example 6 | TMAH | 0.26 | Phenyltrimethyl | 1 | Propylene glycol | 1 |
| | | | ammonium iodide | | monopropyl ether | |
| Example 7 | TMAH | 0.26 | Propyltrimethyl | 5 | Triethylene glycol | 1 |
| | | | ammonium iodide | | monobutyl ether | |
| Example 8 | TMAH | 0.26 | Propyltrimethyl | 1 | Triethylene glycol | 1 |
| | | | ammonium iodide | | monobutyl ether | |
| Example 9 | TPAH | 0.26 | Tetramethyl | 3 | Diethylene glycol | 2 |
| | | | ammonium iodide | | monobutyl ether | |
| Example 10 | TPAH | 0.26 | Tetramethyl | 1 | Diethylene glycol | 1 |
| | | | ammonium iodide | | monobutyl ether | |
| Example 11 | TBAH | 0.26 | Tetramethyl | 3 | Diethylene glycol | 2 |
| | | | ammonium iodide | | monobutyl ether | |
| Example 12 | TBAH | 0.26 | Tetramethyl | 1 | Diethylene glycol | 1 |
| | | | ammonium iodide | | monobutyl ether | |
| Example 13 | TMAH | 0.26 | Tetraethyl | 1 | — | — |
| | | | ammonium iodide | | | |
| Example 14 | TMAH | 0.26 | Ethyltrimethyl | 1 | Triethylene glycol | 1 |
| | | | ammonium iodide | | monobutyl ether | |
| Example 15 | TPAH | 0.26 | Ethyltrimethyl | 1 | — | — |
| | | | ammonium iodide | | | |
| Example 16 | TPAH | 0.26 | Tetramethyl | 1 | Diethylene glycol | 1 |
| | | | ammonium iodide | | monobutyl ether | |
| Example 17 | TPAH | 0.26 | Propyltrimethyl | 1 | — | — |
| | | | ammonium iodide | | | |
| Example 18 | TBAH | 0.26 | Ethyltrimethyl | 1 | — | — |
| | | | ammonium iodide | | | |
| Example 19 | TBAH | 0.26 | Ethyltrimethyl | 1 | Propylene glycol | 1 |
| | | | ammonium iodide | | monopropyl ether | |
| Example 20 | TMAH | 0.26 | Phenyltrimethyl | 3 | Diethylene glycol | 1 |
| | | | ammonium iodide | | monobutyl ether | |
| Comparative | TMAH | 0.26 | — | — | — | — |
| Example 1 | | | | | | |
| Comparative | TEAH | 0.26 | — | — | — | — |
| Example 2 | | | | | | |
| Comparative | TPAH | 0.26 | — | — | — | — |
| Example 3 | | | | | | |
| Comparative | TBAH | 0.26 | — | — | — | — |
| Example 4 | | | | | | |
| Comparative | TMAH | 0.26 | — | — | Diethylene glycol | 2 |
| Example 5 | | | | | monobutyl ether | |
| Comparative | KOH | 3.08 | — | — | — | — |
| Example 6 | | | | | | |
| Comparative | TMAH | 0.26 | — | — | — | — |
| Example 7 | | | | | | |
| Comparative | TEAH | 0.26 | — | — | — | — |
| Example 8 | | | | | | |
| Comparative | TPAH | 0.26 | — | — | — | — |
| Example 9 | | | | | | |
| Comparative | TBAH | 0.26 | — | — | — | — |
| Example 10 | | | | | | |
| Comparative | TMAH | 0.26 | — | — | — | — |
| Example 11 | | | | | | |

Silicon Etching Liquid

| | Quaternary | | | |
|---|---|---|---|---|
| | ammonium | | | |
| | salt | | | |
| | (Compound | | | |
| | represented | Content | Polyhydroxy | Content |
| | by formula (4)) | (wt. %) | compound | (wt. %) |
| Example 1 | — | — | — | — |
| Example 2 | — | — | — | — |
| Example 3 | Decyltrimethyl | 1 | — | — |
| | ammonium bromide | | | |
| Example 4 | Decyltrimethyl | 3 | — | — |
| | ammonium bromide | | | |
| Example 5 | — | — | — | — |
| Example 6 | Octyltrimethyl | 3 | — | — |
| | ammonium bromide | | | |
| Example 7 | — | — | — | — |
| Example 8 | Octyltrimethyl | 3 | — | — |
| | ammonium chloride | | | |
| Example 9 | — | — | — | — |
| Example 10 | Dodecyltrimethyl | 3 | — | — |
| | ammonium bromide | | | |
| Example 11 | — | — | — | — |
| Example 12 | Dodecyltrimethyl | 3 | — | — |
| | ammonium bromide | | | |
| Example 13 | Decyltrimethyl | 1 | Glycerin | 20 |
| | ammonium bromide | | ethylene glycol | 20 |
| Example 14 | Octyltrimethyl | 1 | Pentaerythritol | 3 |
| | ammonium bromide | | glycerin | 20 |
| Example 15 | — | — | Diglycerin | 10 |
| Example 16 | — | — | Ethylene glycol | 30 |
| Example 17 | Decyltrimethyl | 1 | Diglycerin | 10 |
| | ammonium bromide | | ethylene glycol | 50 |
| Example 18 | — | — | Pentaerythritol | 3 |
| Example 19 | Octyltrimethyl | 1 | Pentaerythritol | 3 |
| | ammonium bromide | | | |
| Example 20 | — | — | — | — |
| Comparative | — | — | — | — |
| Example 1 | | | | |
| Comparative | — | — | — | — |
| Example 2 | | | | |
| Comparative | — | — | — | — |
| Example 3 | | | | |
| Comparative | — | — | — | — |
| Example 4 | | | | |
| Comparative | — | — | — | — |
| Example 5 | | | | |
| Comparative | — | — | — | — |
| Example 6 | | | | |
| Comparative | — | — | — | — |
| Example 7 | | | | |
| Comparative | — | — | — | — |
| Example 8 | | | | |
| Comparative | — | — | — | — |
| Example 9 | | | | |
| Comparative | — | — | — | — |
| Example 10 | | | | |
| Comparative | Octyltrimethyl | 5 | — | — |
| Example 11 | ammonium bromide | | | |

TABLE 2

| | | Si(100)/SiGe | Surface state | | Si(100/111) | Selection | |
|---|---|---|---|---|---|---|---|
| | | etching | evaluation * | | etching | ratio | |
| | Processing | selection ratio | Visual | FE-SEM | selection ratio | evaluation (A-D) | |
| | temperature | (R₁₀₀/R_{SiGe}) | evaluation | evaluation | (R₁₀₀/R₁₁₁₎ | Si/SiO₂ | Si/SiN |
| Example 1 | 60 | 110 | 1 | 0 | 6.1 | A | A |
| Example 2 | 60 | 160 | 1 | 0 | 6.6 | A | A |
| Example 3 | 60 | 100 | 5 | 5 | 5.0 | A | A |
| Example 4 | 60 | 130 | 5 | 5 | 2.6 | A | A |
| Example 5 | 60 | 160 | 1 | 0 | 6.8 | A | A |
| Example 6 | 60 | 120 | 3 | 5 | 3.0 | A | A |
| Example 7 | 60 | 150 | 1 | 0 | 7.0 | A | A |
| Example 8 | 60 | 110 | 3 | 5 | 2.9 | A | A |
| Example 9 | 60 | 130 | 1 | 0 | 5.8 | A | A |
| Example 10 | 60 | 110 | 5 | 5 | 2.5 | A | A |
| Example 11 | 60 | 120 | 1 | 0 | 5.6 | A | A |
| Example 12 | 60 | 100 | 5 | 5 | 2.6 | A | A |
| Example 13 | 40 | 120 | 5 | 5 | 2.4 | A | A |
| Example 14 | 40 | 130 | 3 | 5 | 2.8 | A | A |
| Example 15 | 40 | 110 | 5 | 5 | 2.1 | A | A |
| Example 16 | 40 | 130 | 3 | 5 | 2.6 | A | A |
| Example 17 | 40 | 100 | 5 | 5 | 1.8 | A | A |
| Example 18 | 40 | 100 | 5 | 5 | 1.9 | A | A |
| Example 19 | 40 | 110 | 5 | 5 | 2.5 | A | A |
| Example 20 | 40 | 160 | 1 | 0 | 6.9 | A | A |
| Comparative Example 1 | 60 | 70 | 1 | 0 | 4.2 | A | A |
| Comparative Example 2 | 60 | 50 | 1 | 0 | 4.0 | A | A |
| Comparative Example 3 | 60 | 40 | 5 | 5 | 2.6 | A | A |
| Comparative Example 4 | 60 | 20 | 5 | 5 | 2.6 | A | A |
| Comparative Example 5 | 60 | 70 | 1 | 0 | 5.0 | A | A |
| Comparative Example 6 | 60 | 50 | 1 | 0 | 7.0 | D | D |
| Comparative Example 7 | 40 | 50 | 1 | 0 | 3.6 | A | A |
| Comparative Example 8 | 40 | 40 | 1 | 0 | 4.0 | A | A |
| Comparative Example 9 | 40 | 50 | 5 | 5 | 2.2 | A | A |
| Comparative Example 10 | 40 | 10 | 5 | 5 | 2.0 | A | A |
| Comparative Example 11 | 60 | 40 | 3 | 5 | 3.1 | A | A |

* Visual evaluation (5, 3, 1, 0), FE-SEM evaluation (5, 3, 0)

1. A silicon etching liquid comprising a quaternary ammonium hydroxide represented by formula (1), a quaternary ammonium iodide represented by formula (2), and water:
R¹¹R¹²R¹³R¹⁴N⁺·OH⁻ (1)
where R¹¹, R¹², R¹³, and R¹⁴ each independently represents an aryl group, a benzyl group, or an alkyl group having carbon number of 1 to 16, and
the alkyl group, the aryl group, or the benzyl group optionally has a hydroxy group as a substituent;
R²¹R²²R²³R²⁴N⁺·I⁻ (2)
where R²¹, R²², R²³, and R²⁴ each represents an aryl group, a benzyl group, or an alkyl group having carbon number of 1 to 10 optionally having a substituent, and are optionally the same groups or different groups from each other.

2. The silicon etching liquid according to claim 1,
wherein a concentration of the quaternary ammonium hydroxide represented by formula (1) is 0.05 mol/L or more and 1.1 mol/L or less, and
a concentration of the quaternary ammonium iodide represented by formula (2) is 0.1 mass % or more and 15 mass % or less.

3. The silicon etching liquid according to claim 1, further comprising a compound represented by formula (3):
R³¹O—(CₘH₂ₘO)ₙ—R³² (3)
where R³¹ represents a hydrogen atom or an alkyl group having carbon number of 1 to 3, R³² represents a hydrogen atom or an alkyl group having carbon number of 1 to 6, m is an integer of 2 to 6, and n is an integer of 1 to 3,
R³¹ and R³² are not hydrogen atoms at the same time, and
in a case of m=2, a total (n+C¹+C²) of n, the carbon number in R³¹ (C¹), and the carbon number in R³² (C²) is five or more.

4. The silicon etching liquid according to claim 3,
wherein a concentration of the compound represented by formula (3) is 0.5 mass % or more and 20 mass % or less.

5. The silicon etching liquid according to claim 1, further comprising a polyhydroxy compound having carbon number of 2 to 12 and having two or more hydroxy groups per molecule.

6. The silicon etching liquid according to claim 5,
wherein a concentration of the polyhydroxy compound is 5 mass % or more and 70 mass % or less.

7. The silicon etching liquid according to claim 1, further comprising a quaternary ammonium salt represented by formula (4):
R⁴¹R⁴²R⁴³R⁴⁴N⁺·X⁻ (4)
where R⁴¹, R⁴², R⁴³, and R⁴⁴ each represents an alkyl group, having carbon number of 1 to 16 and optionally having a substituent, and are optionally the same groups or different groups from each other, and
X represents BF₄, a fluorine atom, a chlorine atom, or a bromine atom.

8. The silicon etching liquid according to claim 7,
wherein a concentration of the quaternary ammonium salt represented by formula (4) is 1 mass % or more and 50 mass % or less.

9. A method for processing a silicon substrate, the silicon substrate containing at least one silicon material selected from the group consisting of a silicon wafer, a silicon single crystal film, a poly-silicon film, and an amorphous silicon film, the method comprising:
etching the at least one silicon material by using the silicon etching liquid according to claim 1.

10. A method for producing a silicon device, the silicon device containing at least one silicon material selected from the group consisting of a silicon wafer, a silicon single crystal film, a poly-silicon film, and an amorphous silicon film, the method comprising:
etching the at least one silicon material by using the silicon etching liquid according to claim 1.
